(19) United States
(12) Patent Application Publication
(10) Pub. No.: US 2018/0308907 A1
(43) Pub. Date: Oct. 25, 2018

(54) PIXEL ARRANGEMENT STRUCTURE, DISPLAY SUBSTRATE, DISPLAY APPARATUS AND METHOD OF FABRICATION THEREOF

(71) Applicant: BOE TECHNOLOGY GROUP CO., LTD., Beijing (CN)

(72) Inventors: Xiaodan Jin, Beijing (CN); Lujiang Huangfu, Beijing (CN); Yinan Liang, Beijing (CN)

(73) Assignee: BOE TECHNOLOGY GROUP CO., LTD., Beijing (CN)

(21) Appl. No.: 15/578,481

(22) PCT Filed: Mar. 8, 2017
(86) PCT No.: PCT/CN2017/075957

§ 371 Date: Nov. 30, 2017

(30) Foreign Application Priority Data
Jul. 22, 2016 (CN) 201610585894.4

(51) Int. Cl. H01L 27/32; H01L 51/00; H01L 51/56

(52) U.S. Cl. CPC H01L 27/3218; H01L 51/56; H01L 51/0011; H01L 51/001

(57) ABSTRACT

A pixel arrangement structure for a display device. The pixel arrangement structure may comprise a first pixel and a second pixel. The first pixel and the second pixel are alternately in a row direction and a column direction. The first pixel and the second pixel each comprise a first sub-pixel, a second sub-pixel, and a third sub-pixel. The first sub-pixel, the second sub-pixel, and the third sub-pixel in the first pixel form a triangular distribution. The first sub-pixel, the second sub-pixel, and the third sub-pixel in the second pixel form an inverted triangular distribution relative to the triangular distribution in the first pixel. The second sub-pixel and the third sub-pixel in each of the first pixel and the second pixel are located on substantially the same row.

### CROSS-REFERENCE TO RELATED APPLICATIONS

This application claims the benefit of the filing date of Chinese Patent Application No. 201610585894.4 filed on Jul. 22, 2016, the disclosure of which is hereby incorporated by reference.

### TECHNICAL FIELD

This invention relates to a display technology, and more particularly, to a pixel arrangement structure, display substrate, display device, and method of manufacturing thereof.

### BACKGROUND

The requirement that display devices have high display resolution increases the difficulty of manufacturing and cost of the display device. In particular, in the present AMOLED (Active Matrix Organic Light-Emitting Diode) field, due to the limitations of the FMM (Fine Metal Mask) technology, it is difficult to produce a high PPI (Pixel per inch, pixel density) display device.

Three sub-pixels RGB are to be arranged within a pixel spacing in the direction perpendicular to the direction of the stripe sub-pixel in a pixel made of stripe RGB sub-pixels (stripe RGB). As such, when pixel density is greater than 300 ppi, it is very difficult for the present FMM process to achieve the desired pixel density.

### BRIEF SUMMARY

Accordingly, one example of the present disclosure is a pixel arrangement structure. The pixel arrangement structure comprises a first pixel and a second pixel. The first pixel has a first side and a third side opposite the first side. The second pixel has a first side and a third side opposite the first side. The first pixel and the second pixel are alternately in a row direction and a column direction. The first pixel and the second pixel each comprise a first sub-pixel, a second sub-pixel, and a third sub-pixel. The first sub-pixel, the second sub-pixel, and the third sub-pixel in the first pixel form a triangular distribution. The first sub-pixel, the second sub-pixel, and the third sub-pixel in the second pixel form an inverted triangular distribution relative to the triangular distribution in the first pixel. The second sub-pixel and the third sub-pixel in each of the first pixel and the second pixel are located on substantially the same row. In one embodiment, the second sub-pixel and the third sub-pixel in each of the first pixel and the second pixel are located on the same row.

The first sub-pixel in each of the first pixel and the second pixel may be at a center region of the pixel. The first sub-pixel in each of the first pixel and the second pixel may be a green sub-pixel. The second sub-pixel and the third sub-pixel in each of the first pixel and the second pixel may be at an edge region of the pixel. In the first pixel, an edge of the second sub-pixel opposite to the first sub-pixel and an edge of the third sub-pixel opposite to the first sub-pixel may be in close proximity to the first side of the first pixel. In the second pixel adjacent to the first pixel in the row direction, an edge of the second sub-pixel opposite to the first sub-pixel and an edge of the third sub-pixel opposite to the first sub-pixel may be in dose proximity to the third side of the second pixel. The first side of the first pixel and the third side of the second pixel may be located on two opposite sides of the first sub-pixels of the first pixel and the second pixel respectively. In the first pixel, the first sub-pixel may be within a region between the third side and the second and third sub-pixels. In the second pixel, the first sub-pixels within a region between the first side and the second and third sub-pixels. In one embodiment, the edge of the second sub-pixel opposite to the first sub-pixel and the edge of the third sub-pixel opposite to the first sub-pixel in the first pixel overlap with the first side. The edge of the second sub-pixel opposite to the first sub-pixel and the edge of the third sub-pixel opposite to the first sub-pixel in the second pixel overlap with the third side.

In the first pixel, a vertical distance from a center of the first sub-pixel to the third side may be smaller than a vertical distance from the center of the first sub-pixel to the first side. In the second pixel, a vertical distance from a center of the first sub-pixel to the first side may be smaller than a vertical distance from the center of the first sub-pixel to the third side.

In each of the first pixel and the second pixel, an edge of the first sub-pixel adjacent to the second sub-pixel and the third sub-pixel may be in close proximity to a second straight line. The second straight line is a line parallel to the row direction and at equal vertical distance to the first side and the third side. In one embodiment, the edge of the first sub-pixel adjacent to the second sub-pixel and the third sub-pixel overlap with the second straight line.

The first sub-pixel, the second sub-pixel, and the third sub-pixel of the same pixel may form an isosceles triangle distribution. Each of the first pixel and the second pixel may be a rectangular or square pixel. In each of the first pixel and the second pixel, the second sub-pixel and the third sub-pixel may be located near two corners of the rectangular or square pixel in the row direction, with two adjacent perpendicular edges of the second sub-pixel and two adjacent perpendicular edges of the third sub-pixel in close proximity to two adjacent perpendicular edges of the rectangular or square pixel, respectively. In one embodiment, the two adjacent perpendicular edges of the second sub-pixel and the two adjacent perpendicular edges of the third sub-pixel overlap with the two adjacent perpendicular edges of the rectangular or square pixel, respectively.

The first sub-pixel may be positioned on a perpendicular bisector of the second sub-pixel and the third sub-pixel. In one embodiment, a center of the first sub-pixel is located on the perpendicular bisector of the second sub-pixel and the third sub-pixel. Each of the first sub-pixel, the second sub-pixel and the third sub-pixel may be a rectangle or square sub-pixel.

The first pixel and the second pixel adjacent to each other in a column direction may be mirror-symmetric. The second sub-pixel and the third sub-pixel in the first pixel are adjacent to the second sub-pixel and the third sub-pixel in the second pixel adjacent to the first pixel in the column direction respectively. In one embodiment, at least one pair of the adjacent second sub-pixels or the adjacent third sub-pixels may be integrated.

Another example of the present disclosure is a display substrate including the pixel arrangement structure in accordance with one embodiment of the present disclosure. The display substrate may be an OLED display substrate.

Another example of the present disclosure is a display device comprising the display substrate in accordance with one embodiment of the present disclosure.

Another example of the present disclosure is a method of manufacturing a display substrate, comprising the steps of forming the display substrate in accordance with one embodiment of the present disclosure. The display substrate may be an OLED display substrate. The method may comprise forming a sub-pixel of the OLED display substrate by an evaporation deposition technique using an FMM mask plate. The FMM mask plate may include at least one first opening. The first opening may correspond to at least two adjacent sub-pixels of the same color.

Another example of the present disclosure is an FMM mask used for forming the display substrate in accordance with one embodiment of the present disclosure. The FMM mask plate may include at least one fast opening. The first opening may correspond to at least two adjacent sub-pixels of the same color.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows a schematic view of a pixel arrangement structure according to one embodiment.

FIG. 2 shows a schematic view of a pixel arrangement structure according to one embodiment.

FIG. 3 shows a schematic view of a pixel arrangement structure according to one embodiment.

FIG. 4 shows a schematic view of a pixel arrangement structure according to one embodiment.

### DETAILED DESCRIPTION

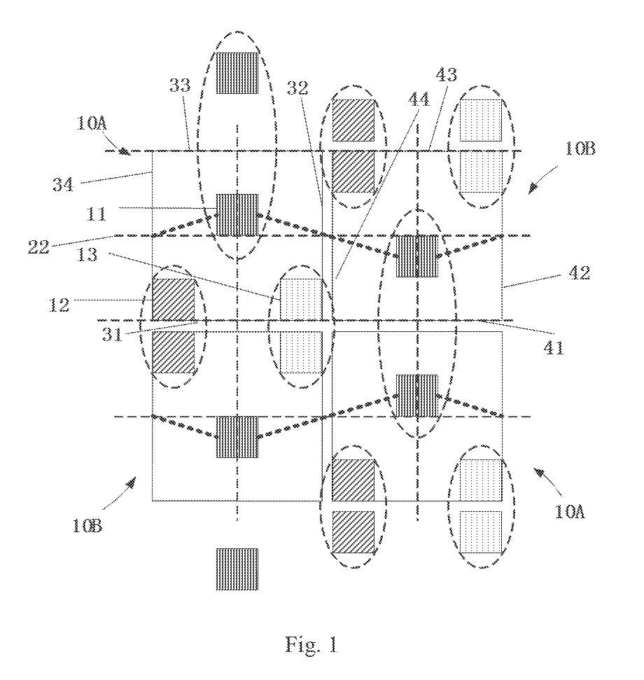

The present disclosure is described with reference to embodiments of the invention. Throughout the description of the invention reference, is made to FIGS. 1-3. When referring to the figures, like structures and elements shown throughout are indicated with like reference numerals.

Unless otherwise defined, technical terms or scientific terms used herein should be in the ordinary meaning as understood by those of ordinary skill in the art to which this invention belongs. The terms “first,” “second,” and the like as used in the specification and claims are not intended to imply any order, quantity or importance, but only to distinguish between the different components. Likewise, the terms “a” and the like do not denote a numerical limitation, but rather denote the presence of at least one. The terms “connected” and the like are not limited to physical or mechanical connections, regardless of whether it is direct or indirect. The terms “upper,” “lower,” “left,” “right” and the like are used only to indicate a relative positional relationship. When the absolute position of the described object is changed, the relative positional relationship is also changed accordingly.

FIG. 1 shows a schematic view of a pixel arrangement structure in accordance with some embodiments of the present disclosure. The pixel arrangement structure comprises: a plurality of first pixels 10A and a plurality of second pixels 10B. The first pixel 10A and the second pixel 10B are alternately arranged in a row direction and a column direction. All pixels surrounding a first pixel 10A are second pixels, and all pixels surrounding a second pixel 10B are first pixels. That is, except pixels at the edges, each of the first pixels is surrounded by the second pixels, and each of the second pixels is surrounded by the first pixels. The first pixel has a first side 31, a second side 32, third side 33 opposite the first side 31, and a fourth side 34 opposite the second side 32. The second pixel has a first side 41, a second side 42, a third side 43 opposite the first side 41, and a fourth side 44 opposite the second side 42. Each of the first pixel 10A and the second pixel 10B includes: a first sub-pixel 11, a second sub-pixel 12, and a third sub-pixel 13.

In one embodiment, the first sub-pixel 11, the second sub-pixel 12, and the third sub-pixel 13 in the first pixel 10A form a triangular distribution. The first sub-pixel 11, the second sub-pixel 12, and the third sub-pixel 13 in the second pixel 10B form an inverted triangular distribution relative to the triangular distribution in the first pixel. The second sub-pixel and the third sub-pixel in each of the first pixel and the second pixel are located on substantially the same row. “Located on substantially the same row” means that an acute angle formed between a line connecting centers of the second sub-pixel and the third sub-pixel and the row direction is smaller than 5 degree.

In one embodiment, the first sub-pixel in the first pixel is at a center region of the first pixel. The first sub-pixel in the second pixel is at a center region of the second pixel. The “center region” means that the center of the first pixel or the second pixel is located at one part of the first sub-pixel of the first pixel or the second pixel respectively.

In one embodiment, the first sub-pixel is a green sub-pixel.

In one embodiment, the second sub-pixel and the third sub-pixel in each of the first pixel and the second pixel are at an edge region of the pixel.

In one embodiment, in the first pixel, an edge of the second sub-pixel 12 and an edge of the third sub-pixel 13 opposite to the first sub-pixel 11 are in close proximity to the first side 31 of the first pixel 10A. “In close proximity to” herein mans that a vertical distance from a center of the second sub-pixel to the first side 31 is smaller than a length of a vertical side of the second sub-pixel, and a vertical distance from a center of the third sub-pixel to the first side is smaller than a length of a vertical side of the third sub-pixel.

In the second pixel adjacent to the first pixel in the row direction, an edge of the second sub-pixel 12 and an edge of the third sub-pixel 13 opposite to the first sub-pixel 11 are in close proximity to the third side 43 of the second pixel 10B. “In close proximity to” herein means that a vertical distance from a center of the second sub-pixel to the third side 43 is smaller than a length of a vertical side of the second sub-pixel, and a vertical distance from a center of the third sub-pixel to the third side 43 is smaller than a length of a vertical side of the third sub-pixel.

The first side 31 of the first pixel 10A and the third side 43 of the second pixel 10B are located on two opposite sides of the first sub-pixels of the first pixel 10A and the second pixel 10B respectively. In the first pixel 10A, the first sub-pixel is within a region between the third side 33 and the second and third sub-pixels. In the second pixel, the first sub-pixel is within a region between the first side 41 and the second and third sub-pixels.

In one embodiment, the edge of the second sub-pixel and the edge of the third sub-pixel opposite to the first sub-pixel in the first pixel overlap with the first side 31. The edge of the second sub-pixel and the edge of the third sub-pixel in the second pixel overlap with the third side 43.

In one embodiment, in the first pixel 10A, a vertical distance from a center of the first sub-pixel to the third side 33 is smaller than a vertical distance from the center of the first sub-pixel to the first side 31. In the second pixel, a vertical distance from a center of the first sub-pixel to the first side 41 is smaller than a vertical distance from the center of the first sub-pixel to the third side 43.

In one embodiment, in each of the first pixel and the second pixel, an edge of the first sub-pixel adjacent to the second sub-pixel and the third sub-pixel is in close proximity to a second straight line 22, which is parallel to the row direction and at equal vertical distance to the first side and the third side. “In close proximity to” herein means that a vertical distance from a center of the first sub-pixel to the second straight line 22 is smaller than a length of a vertical side of the first sub-pixel.

In one embodiment, the edge of the first sub-pixel adjacent to the second sub-pixel and the third sub-pixel overlap with the second straight line 22.

In one embodiment, the first sub-pixel, the second sub-pixel, and the third sub-pixel of the same pixel form an isosceles triangle distribution. Each of the first pixel and the second pixel may be a rectangular or square pixel.

In one embodiment, in each of the first pixel and the second pixel, the second sub-pixel and the third sub-pixel are located near two corners of the rectangular or square pixel in the row direction, with two adjacent perpendicular edges of the second sub-pixel and two adjacent perpendicular edges of the third sub-pixel in close proximity to two adjacent perpendicular edges of the rectangular or square pixel, respectively. “In close proximity to” herein means that a vertical distance from a center of a sub-pixel to a side of the pixel is smaller than a length of a perpendicular side of the sub-pixel, which is perpendicular to the side of the pixel.

In one embodiment, the two adjacent perpendicular edges of the second sub-pixel and the two adjacent perpendicular edges of the third sub-pixel overlap with the two adjacent perpendicular edges of the rectangular of square pixel, respectively.

In one embodiment, in each of the first pixel and the second pixel, the first sub-pixel is positioned on a perpendicular bisector of the second sub-pixel and the third sub-pixel. In another embodiment, in each of the first pixel and the second pixel, a center of the first sub-pixel is located on the perpendicular bisector of the second sub-pixel and the third sub-pixel.

In one embodiment, the second sub-pixel and third pixel in the first pixel are adjacent to the second sub-pixel and third pixel in the second pixel adjacent to the first pixel in the column direction.

In one embodiment, as shown in FIG. 1, in a row direction, three sub-pixels of different colors are arranged within a spacing of two adjacent pixels of the same row. In the column direction, two sub-pixels of the same color are arranged within a spacing of two adjacent pixels of the same column. Compared with the conventional art, where six sub-pixels are arranged within a spacing of two adjacent pixels in the row direction, and two sub-pixels are arranged within a spacing of two adjacent pixels in the column direction, this embodiment reduces the number of sub-pixels significantly, thereby reducing the difficulty of manufacturing the pixels, and making it possible to produce a display device having a high PPI (e.g., a resolution of 500 ppi or more).

In one embodiment, in the same column, only two sub-pixels of the same color are included, and the two sub-pixels are adjacent to each other (see the two sub-pixels in the same elliptical dashed-line frame in FIG. 1. During the vapor deposition technique to form the sub-pixels in accordance with some embodiments, the number of sub-pixels within the spacing of the same number of pixels is reduced. The two adjacent sub-pixels located in the same elliptical dashed-line frame can be formed by one FMM opening evaporation. Accordingly, the number (density) of the FMM openings can be effectively reduced, thereby breaking through the limitation of the FMM technology for high-resolution AMOLED, and achieving 300 ppi or higher resolution of AMOLED.

In one embodiment, the pixels in the pixel arrangement structure are Real (real) pixels. Accordingly, even in the high PPI, the graphical image display is still relatively clear. This is particularly important for some displays of special graphics or images. For example, displays of pointers of electronic display watches and other details show a smooth, sharp feeling.

In one embodiment, as shown in FIG. 1, in the same column, the adjacent first and second pixels 10A and 10B are mirror-symmetric. That is, the arrangement structure of the first sub-pixel 11, the second sub-pixel 12, and the third sub-pixel 13 in the second pixel 10B is mirror-symmetric with that of the first sub-pixel 11, the second sub-pixel 12, and the third sub-pixel in the first pixel 10A.

In one embodiment, in the same column, adjacent first and second pixels 10A and 10B are not mirror-symmetric; for example, the center of the first sub-pixel 11 of the first pixel 10A and the center of the first cub-pixel 11 of the second pixel 10B may not be on the same straight line.

In one embodiment, in the same pixel, the first sub-pixel 11, the second sub-pixel 12, and the third sub-pixel 13 have an isosceles triangle distribution. That is, the lines connecting the centers of the first sub-pixel 11, the second sub-pixel 12, and the third sub-pixel 13 form an isosceles triangle. In another embodiment, the first sub-pixel 11, the second sub-pixel 12, and the third sub-pixel 13 have an equilateral triangle distribution.

In one embodiment, in the column direction, a vertical distance from the first sub-pixel to a line connecting centers of the second sub-pixel or the third sub-pixel in the same pixel is larger than a vertical distance from the same first sub-pixel to a line connecting centers of another second sub-pixel and another third sub-pixel in another adjacent pixel in the row direction.

In one embodiment, in the same pixel, an edge of the first sub-pixel 11, which is parallel to the row direction and adjacent to the second sub-pixel 12 and the third sub-pixel 13, is located on a second straight line 22. In one embodiment, the second straight line 22 is parallel to the first side and located between the first side and the third side. In one embodiment, the distances from the second straight line 22 to the first side and to the third side are the same. The distance between two straight lines generally refers to the vertical distance between the two straight lines.

In one embodiment, the first sub-pixel 11, the second sub-pixel 12, and the third sub-pixel 13 are all rectangular sub-pixels. Based on actual needs of production, these sub-pixels may be formed into other shapes such as a circle, a triangle, a parallelogram, etc., and the present disclosure is not limited thereto.

In one embodiment, the first pixel 10A and the second pixel 10B each is a rectangular pixel. Preferably, the first pixel 10A and the second pixel 10B each is a square pixel, which makes the distribution of the sub-pixels more uniform and improves the quality of display. Based on actual production needs, other shapes such as a circle, a triangle, a parallelogram, and the like may also be made, and the present invention is not limited thereto.

In another embodiment, the first sub-pixel 11 is a sub-pixel having a larger impact on brightness of the pixel, and the second sub-pixel 12 and the third sub-pixel 13 are sub-pixels having a smaller impact on brightness of the pixel. That is, the impact on brightness of the pixel by the first sub-pixel 11 in the pixel is larger than that of the second sub-pixel 12 and the third sub-pixel 13 in the pixel, thereby making the brightness distribution of the pixels more uniform, and improving the display quality of the display device.

In one embodiment, in the same pixel, the second sub-pixel 12 and the third sub-pixel 13 are located at two ends of one side of the rectangular pixel. Preferably, two perpendicular edges of the second sub-pixel 12 and two perpendicular edges of the third sub-pixel 13 are in close proximity to two adjacent perpendicular edges of the pixel. In other embodiments, two perpendicular edges of the second sub-pixel 12 and two perpendicular edges of the third sub-pixel 13 completely overlap to two adjacent perpendicular edges of the pixel. In other embodiments of the present invention, there may be possibility of fine adjustment of the positions of the second sub-pixel 12 or the third sub-pixel 13.

In one embodiment, when the pixel is a rectangular pixel, in the same pixel, the first sub-pixel 11 is positioned on a perpendicular bisector between the second sub-pixel 12 and the third sub-pixel 13. Preferably, a center of the first sub-pixel 11 is located on the perpendicular bisector between the second sub-pixel 12 and the third sub-pixel 13.

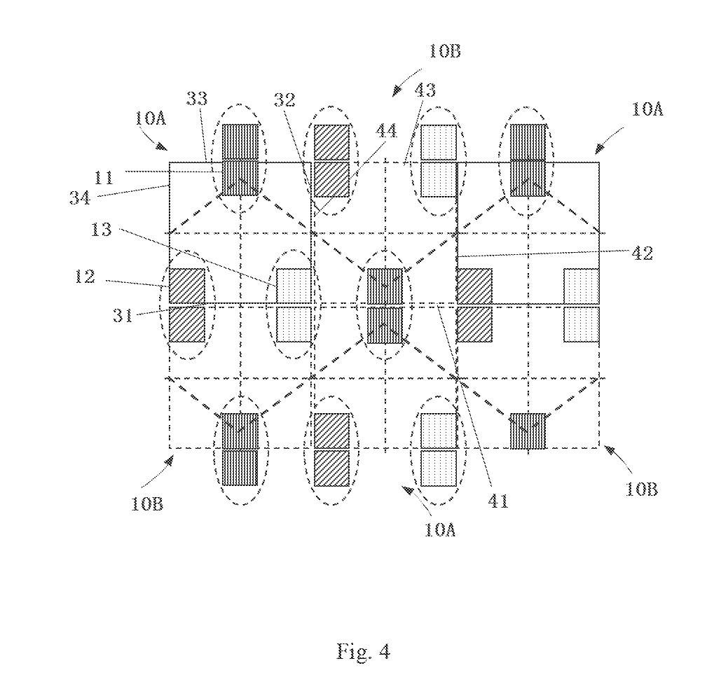

In one embodiment, in the first pixel, when the pixel is a rectangular pixel, the vertical distance from a center of the first sub-pixel 11 to the first side is larger than that from the center of the first sub-pixel 11 to the third side (contrast with the first side). In the second pixel adjacent to the first pixel, the distance from a center of the first sub-pixel 11 to the third side is larger than that from the center of first sub-pixel 11 to the first side. Accordingly, the first sub-pixel 11 is more uniformly distributed along the first pixel and the second pixel than the embodiment as shown in FIG. 4.

FIG. 4 shows a schematic view of a pixel arrangement structure in accordance with one embodiment o the present invention. In one embodiment, as shown in FIG. 4, in the first pixel, an edge of the first sub-pixel opposite to the second pixel and the third pixel overlaps with the third side 33. In the second pixel, an edge of the first sub-pixel opposite to the second pixel and the third pixel overlaps with the fist side 41.

In one embodiment, in the same pixel, an edge of the first sub-pixel 11, which is parallel and adjacent to the first side, is in close proximity to the perpendicular bisector of the second side of the pixel. In other embodiments of the present invention, the first sub-pixel 11 may be provided at another position, such as other locations between the third side and the perpendicular bisector of the second side of the pixel.

As the human eye is more sensitive to green color, while not too sensitive to red and blue colors, in one embodiment, the first sub-pixel 11 may be a green sub-pixel, the second sub-pixel 12 may be a red sub-pixel on a blue sub-pixel, and the third sub-pixel 13 may be a blue or red sub-pixel. The possibility of using sub-pixels of other colons is not excluded.

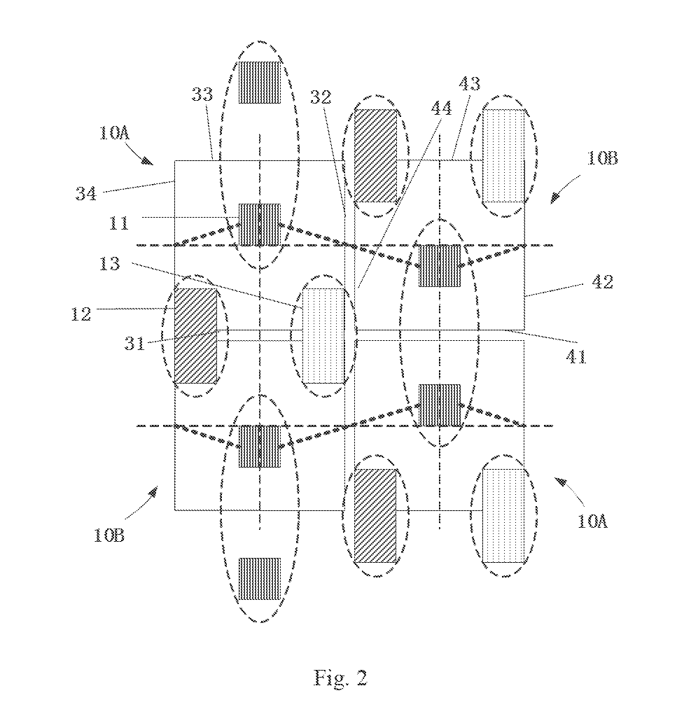

FIG. 2 shows a schematic view of a pixel arrangement structure in accordance with one embodiment of the present invention. This embodiment differs from the embodiment shown in FIG. 1 in that, in the same column, the second sub-pixels 12 and the third sub-pixels 13 of adjacent first and second pixels 10A and 10B, which are mirror-symmetrical, are integrated, which is then shared by the first pixel 10A and the second pixel 10B through Sup-Pixel Rendering (SPR) algorithm driving. The means that the second sub-pixel 12 in the first pixel 10A and that in the second pixel 10B have a unitary structure. The third sub-pixel 13 in the first pixel 10A and that in the second pixel 10B have a unitary structure. But during display, one of ordinary skill in the art would understand that it is possible to separately control the light emission thereof.

The so-called SPR technology (derived from the virtual pixel reconstruction) refers to, when the display resolution level is equivalent to human eye resolution level, it is possible to utilize the difference in the resolution of the human eye with respect to sub-pixels of different colors to change the conventional model of the pixel (Pixel) simply defined by sub-pixels of three-colors, red, green, and blue (R, G, B). Different pixels also can share some sub-pixels having colors which are insensitive to location resolution. As such, it is possible to use a relatively smaller number of sub-pixels to imitatively achieve the same pixel resolution performance capabilities, thereby reducing the difficulty of processing and the cost.

In one embodiment, the second sub-pixels 12 located in the adjacent first and second pixels 10A and 10B respectively in the same column are integrated. The third sub-pixels 13 located in the adjacent first and second pixels 10A and 10B respectively in the same column are integrated. In another embodiment, only one pair of the first and second sub-pixels 12 or third sub-pixels 13 in the adjacent first and second pixels 10A and 10B are merged into one pixel.

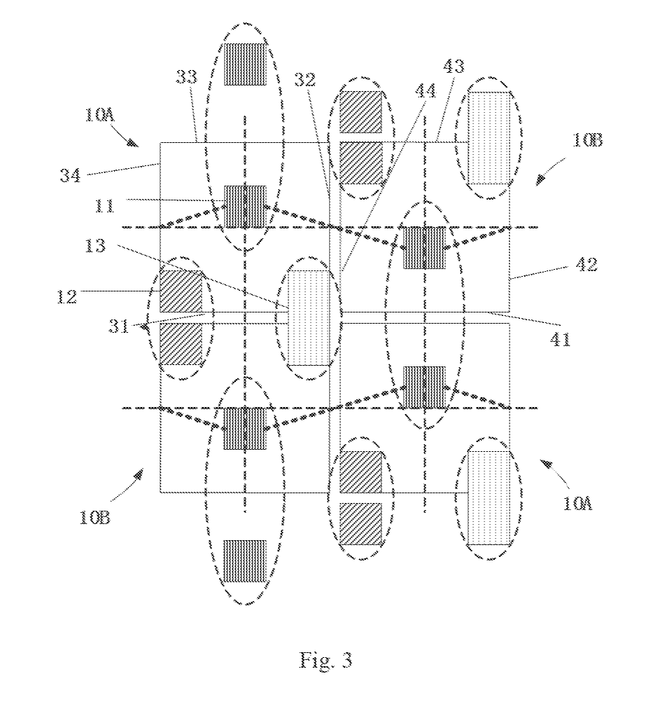

FIG. 3 shows a schematic view of a pixel arrangement structure in accordance with one embodiment of the present invention. This embodiment differs from the embodiment shown in FIG. 1 in that, in the same column, the third sub-pixels 13 in the adjacent first sub-pixel 10A and the second pixel 10B, which are mirror-symmetrical, in the same column are integrated, driven by the SPR algorithm and shared by the first pixel 10A and the second pixel 10B.

As the human eye is least sensitive to the blue color, it is preferable that the third sub-pixel 13 is a blue sub-pixel.

In another embodiment, the first sub-pixels in the adjacent first pixel and the second pixel in the same column may be shared as well, for example, the two first sub-pixels located in the same elliptical dotted circle in FIG. 3 may be shared.

The embodiment of the present invention also provides a display substrate, including the pixel arrangement structure in any of the above embodiments.

Preferably, the display substrate may be an OLED display substrate.

One embodiment of the present invention also provides a display device including the above-described display substrate.

According to one embodiment of the present invention, a method manufacturing a display substrate is also provided for producing the display substrate.

In the embodiment, the display substrate is an OLEO display substrate, and the manufacturing method may include: forming a sub-pixel of the OLED display substrate by an evaporation deposition technology using an FMM mask plate. The FMM mask plate may include at least one first opening, and the first opening may correspond to at least two adjacent sub-pixels of the same color.

One embodiment of the invention also provides an FMM mask plate, which can be used to form the OLED display substrate. The FMM mask plate includes at least one first opening, and the first opening may correspond to at least two adjacent sub-pixels of the same color.

The descriptions of the various embodiments of the present invention have been presented for purposes of illustration, but are not intended to be exhaustive and the limitation is not limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A pixel arrangement structure, comprising:
a first pixel having a first side and a third side opposite the first side, and
a second pixel having a first side and a third side opposite the first side,
the first pixel and the second pixel each comprising:
a first sub-pixel,
a second sub-pixel, and
a third sub-pixel,
wherein the first pixel and the second pixel are alternately in a row direction and a column direction;
the first sub-pixel, the second sub-pixel, and the third sub-pixel in the first pixel form a triangular distribution;
the first sub-pixel, the second sub-pixel, and the third sub-pixel in the second pixel form an inverted triangular distribution relative to the triangular distribution in the first pixel; and
the second sub-pixel and the third sub-pixel in each of the first pixel and the second pixel are located on substantially the same row.

2. The pixel arrangement structure according to claim 1, wherein the second sub-pixel and the third sub-pixel in each of the first pixel and the second pixel are located on the same row.

3. The pixel arrangement structure according to claim 1, wherein the first sub-pixel in each of the first pixel and the second pixel is at a center region of the pixel.

4. The pixel arrangement structure according to claim 1, wherein the first sub-pixel in each of the first pixel and the second pixel is a green sub-pixel.

5. The pixel arrangement structure according to claim 1, wherein the second sub-pixel and the third sub-pixel in each of the first pixel and the second pixel are at an edge region of the pixel.

6. The pixel arrangement structure according to claim 1, wherein
in the first pixel, an edge of the second sub-pixel opposite to the first sub-pixel and an edge of the third sub-pixel opposite to the first sub-pixel are in close proximity to the first side of the first pixel;
in the second pixel adjacent to the first pixel in the row direction, an edge of the second sub-pixel opposite to the first sub-pixel and an edge of the third sub-pixel opposite to the first sub-pixel are in close proximity to the third side of the second pixel;
the first side of the first pixel and the third side of the second pixel are located on two opposite sides of the first sub-pixels of the first pixel and the second pixel respectively;
in the first pixel, the first sub-pixel is within a region between the third side and the second and third sub-pixels; and
in the second pixel, the first sub-pixel is within a region between the first side and the second and third sub-pixels.

7. The pixel arrangement structure according to claim 6, wherein the edge of the second sub-pixel opposite to the first sub-pixel and the edge of the third sub-pixel opposite to the first sub-pixel in the first pixel overlap with the first side; and
the edge of the second sub-pixel opposite to the first sub-pixel and the edge of the third sub-pixel opposite to the first sub-pixel in the second pixel overlap with the third side.

8. The pixel arrangement structure according to claim 1, wherein:
in the first pixel, a vertical distance from a center of the first sub-pixel to the third side is smaller than a vertical distance from the center of the first sub-pixel to the first side; and
in the second pixel, a vertical distance from a center of the first sub-pixel to the first side is smaller than a vertical distance from the center of the first sub-pixel to the third side.

9. The pixel arrangement structure according to claim 1, wherein in each of the first pixel and the second pixel, an edge of the first sub-pixel adjacent to the second sub-pixel and the third sub-pixel is in close proximity to a second straight line, the second straight line being parallel to the row direction and at equal vertical distance to the first side and the third side.

10. The pixel arrangement structure according to claim 9, wherein the edge of the first sub-pixel adjacent to the second sub-pixel and the third sub-pixel overlap with the second straight line.

11. The pixel arrangement structure according to claim 1, wherein the first sub-pixel, the second sub-pixel, and the third sub-pixel of the same pixel form an isosceles triangle distribution.

12. The pixel arrangement structure according to claim 1, wherein each of the first pixel and the second pixel is a rectangular or square pixel.

13. The pixel arrangement structure according to claim 12, wherein in each of the first pixel and the second pixel, the second sub-pixel and the third sub-pixel are located near two corners of the rectangular or square pixel in the row direction, with two adjacent perpendicular edges of the second sub-pixel and two adjacent perpendicular edges of the third sub-pixel in close proximity to two adjacent perpendicular edges of the rectangular or square pixel, respectively.

14. The pixel arrangement structure according to claim 13, wherein the two adjacent perpendicular edges of the second sub-pixel and the two adjacent perpendicular edges of the third sub-pixel overlap with the two adjacent perpendicular edges of the rectangular or square pixel, respectively.

15. The pixel arrangement structure according to claim 1, wherein the first sub-pixel is positioned on a perpendicular bisector of the second sub-pixel and the third sub-pixel.

16. The pixel arrangement structure according to claim 15, wherein a center of the first sub-pixel is located on the perpendicular bisector of the second sub-pixel and the third sub-pixel.

17. The pixel arrangement structure according to claim 1, wherein each of the first sub-pixel, the second sub-pixel and the third sub-pixel is a rectangle or square sub-pixel.

18. The pixel arrangement structure according to claim 1, wherein the first pixel and the second pixel adjacent to each other in a column direction are mirror-symmetric.

19. The pixel arrangement structure according to claim 1, wherein the second sub-pixel and the third sub-pixel in the first pixel are adjacent to the second sub-pixel and the third sub-pixel in the second pixel adjacent to the first pixel in the column direction respectively.

20. The pixel arrangement structure according to claim 19, wherein at least one pair of the adjacent second sub-pixels or the adjacent third sub-pixels is integrated.

21. A display substrate, comprising the pixel arrangement structure of claim 1.
